(19) United States
(12) Patent Application Publication
(10) Pub. No.: US 2010/0051911 A1
(43) Pub. Date: Mar. 4, 2010

(54) Organic Thin Film Transistor Array Panel and Method of Manufacturing the Same

(76) Inventors: Seung-Hwan Cho, Suwon-si (KR); Bo-Sung Kim, Seoul (KR); Young-Min Kim, Yongin-si (KR); Shi-Woo Rhee, Pohang-si (KR); Dong-Jin Yun, Cheongju-si (KR)

Correspondence Address: F. CHAU & ASSOCIATES, LLC, 130 WOODBURY ROAD, WOODBURY, NY, 11797, US

(21) Appl. No.: 12/391,883

(22) Filed: Feb. 24, 2009

(30) Foreign Application Priority Data
Sep. 3, 2008 (KR) 10-2008-0086897

(51) Int. Cl. H01L 51/50; H01L 51/56

(52) U.S. Cl. 257/40; 438/34; 257/E51.018; 257/E21.412

(57) ABSTRACT

In an organic thin film transistor array panel includes a source electrode and a drain electrode having a double layer including a metal and a metal oxide. The organic thin film transistor array panel is formed through a lift-off process or by using a shadow mask. The thin film transistor array panel has excellent characteristics and reduced manufacturing process costs.

### CROSS-REFERENCE TO RELATED APPLICATION

This application claims priority to and the benefit of Korean Patent Application No. 10-2008-0086897 filed in the Korean Intellectual Property Office on Sep. 3, 2008, the entire contents of which are incorporated herein by reference.

### BACKGROUND OF THE INVENTION

(a) Technical Field

The present invention relates to thin film transistors, and more particularly, to a thin film transistor array panel and a manufacturing method thereof.

(b) Discussion of the Related Art

Generally, a flat panel display, such as a liquid crystal display (LCD), an organic light emitting diode (OLED) display, and an electrophoretic display, includes a plurality of pairs of field generating electrodes and an electro-optical activation layer disposed therebetween. The liquid crystal display includes a liquid crystal layer as the electro-optical activation layer, and the organic light emitting diode display includes an organic emission layer as the electro-optical activation layer.

One of the pairs of field generating electrodes is generally connected to a switching element so as to receive an electrical signal, and the electro-optical activation layer converts the electrical signal to an optical signal, thereby displaying images.

In the flat panel display, a thin film transistor (TFT), which includes a gate electrode, a source electrode, a drain electrode, and a semiconductor, is used as the switching element. A gate line transmitting a scanning signal is used to control the thin film transistor. A data line transmitting a signal applied to a pixel electrode are provided to the flat panel display.

Among such thin film transistors, research on an organic thin film transistor (OTFT), using an organic semiconductor instead of an inorganic semiconductor such as silicon Si, is being undertaken.

The organic thin film transistor may be manufactured by a solution process for the organic semiconductor and the insulating layer, so it may be easily applied to a large size flat panel display that would otherwise be difficult to perform a deposition process on.

The organic thin film transistor array panel in which the organic thin film transistors are arranged in a matrix shape has many differences in structure and manufacturing process compared with the conventional thin film transistor.

### SUMMARY OF THE INVENTION

A thin film transistor array panel according to an exemplary embodiment of the present invention includes a gate line including a gate electrode. An interlayer insulating layer is formed on the gate line. A data line is formed on the interlayer insulating layer and includes a source electrode. A drain electrode faces the source electrode. An organic semiconductor is formed between the source electrode and the drain electrode. A pixel electrode is connected to the drain electrode. The data line and the drain electrode include a first data line and a first drain electrode including a metal, and a second data line and a second drain electrode formed on the first data line and the first drain electrode and including a metal oxide.

The organic semiconductor may contact the second data line and the second drain electrode.

The second data line and the second drain electrode may fully cover the first data line and the first drain electrode, respectively.

The first data line and the first drain electrode may have substantially the same plane shape as the second data line and the second drain electrode, respectively.

The organic semiconductor may contact the interlayer insulating layer. The organic semiconductor may be thinner than the source electrode or the drain electrode. The organic semiconductor may be formed on the second data line and the second drain electrode.

The metal and the metal oxide may include a first metal. The first metal may be molybdenum (Mo), copper (Cu), rubidium (Ru), vanadium (V), chromium (Cr), zinc (Zn), indium (In), or aluminum (Al). The value of the work function of the metal oxide may be in the range of about 4.8-5.5 eV

A passivation layer formed on the organic semiconductor, the second data line, and the second drain electrode may be included.

A manufacturing method of a thin film transistor array panel according to an exemplary embodiment of the present invention includes forming a gate line including a gate electrode. An interlayer insulating layer is formed on the gate line. A photosensitive film pattern is formed on the interlayer insulating layer for forming a data line including a source electrode and a drain electrode. A data metal layer is deposited on the photosensitive film pattern and the interlayer insulating layer. A data metal oxide layer is formed on the data metal layer. The photosensitive film pattern is removed. An organic semiconductor is formed between the source electrode and the drain electrode.

The photosensitive film may include a negative photosensitive material.

The organic semiconductor may be formed on the metal oxide layer. The organic semiconductor may contact the metal oxide layer.

The method may further include forming a passivation layer on the organic semiconductor.

The method may further include forming a pixel electrode on the passivation layer.

A manufacturing method of a thin film transistor array panel according to an exemplary embodiment of the present invention includes forming a gate line including a gate electrode. An interlayer insulating layer is formed on the gate line. An assistance metal layer is formed on the interlayer insulating layer. A photosensitive film pattern is formed on the assistance metal layer for forming a data line including a source electrode and a drain electrode. The assistance metal layer is etched by using the photosensitive film pattern as a mask. A data metal layer is deposited on the photosensitive film pattern and the interlayer insulating layer; forming a data metal oxide layer on the data metal layer. The photosensitive film pattern and the assistance metal layer are removed. An organic semiconductor is formed between the source electrode and the drain electrode.

A manufacturing method of a thin film transistor array panel according to an exemplary embodiment of the present invention includes forming a gate line including a gate electrode. An interlayer insulating layer is formed on the gate line. A mask is aligned on the interlayer insulating layer for forming a data line including a source electrode and a drain electrode. A data metal layer and a data metal oxide layer are deposited through the opening of the mask to form the data line including the source electrode and the drain electrode. An organic semiconductor is formed between the source electrode and the drain electrode. According to an exemplary embodiment of the present invention, the source electrode and the drain electrode having the double layers of the metal and the metal oxide are formed through a lift-off process or a shadow mask process such that the characteristics of the thin film transistor may be increased and the manufacturing process cost of the thin film transistor array panel may be reduced.

### BRIEF DESCRIPTION OF THE DRAWINGS

The above and other features and aspects of the exemplary embodiments of the present invention will be described in detail with reference to the accompanying drawings, in which:

FIG. 1 is a layout view of a thin film transistor array panel according to an exemplary embodiment of the present invention;

FIG. 2 is a cross-sectional view of the thin film transistor array panel shown in FIG. 1 taken along the line II-II;

FIG. 3 to FIG. 8 are layout views sequentially showing a method for manufacturing an organic thin film transistor array panel shown in FIG. 1 and FIG. 2 according to an exemplary embodiment of the present invention;

FIG. 9 to FIG. 13 are layout views sequentially showing a method for manufacturing an organic thin film transistor array panel shown in FIG. 1 and FIG. 2 according to an exemplary embodiment of the present invention; and

FIG. 14 to FIG. 16 are layout views sequentially showing a method for manufacturing an organic thin film transistor array panel shown in FIG. 1 and FIG. 2 according to an exemplary embodiment of the present invention.

### DETAILED DESCRIPTION OF THE EXEMPLARY EMBODIMENTS

Exemplary embodiments of the present invention will be described more fully hereinafter with reference to the accompanying drawings. As those skilled in the art would realize, the described embodiments may be modified in various different ways, all without departing from the spirit or scope of the present invention.

In the drawings, the thickness of layers, films, panels, regions, etc., may be exaggerated for clarity. Like reference numerals may designate like elements throughout the specification. It will be understood that when an element such as a layer, film, region, or substrate is referred to as being “on” another element, it can be directly on the other element or intervening elements may also be present.

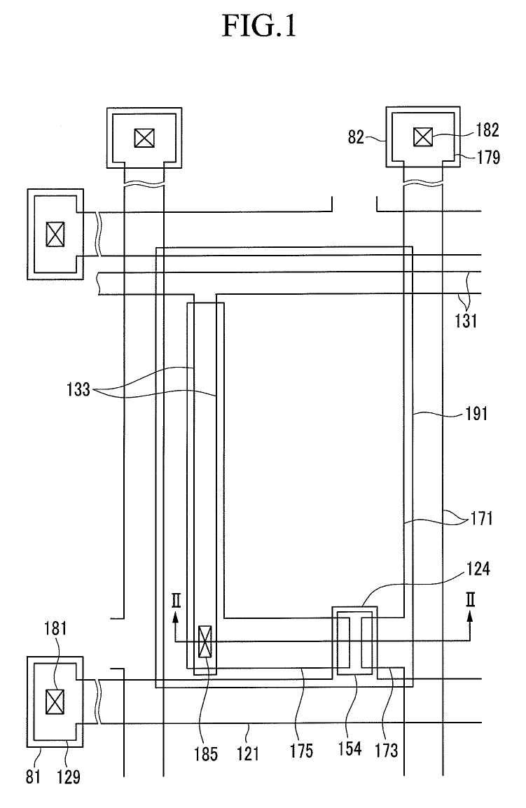

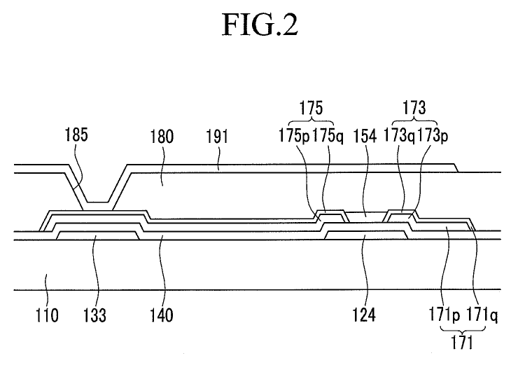

Now, a thin film transistor array panel according to an exemplary embodiment of the present invention will be described with reference to FIG. 1 and FIG. 2.

FIG. 1 is a layout view of a thin film transistor array panel according to an exemplary embodiment of the present invention, and FIG. 2 is a cross-sectional view of the thin film transistor array panel shown in FIG. 1 taken along the line II-II.

Gate lines 121 and storage electrode lines 131 are formed on an insulating substrate 110 comprising a material such as transparent glass or plastic.

The gate lines 121 transmit gate signals and extend in a transverse direction. Each of the gate lines 121 includes a plurality of gate electrodes 124 protruding upward and an end portion 129 for connection with another layer or an external driving circuit.

The storage electrode lines 131 receive a predetermined voltage and are substantially parallel to the gate lines 121. Each storage electrode line 131 is disposed between two gate lines 121 and includes a storage electrode 133 extending in a lower direction. However, the shape and arrangement of the storage electrode lines 131 and the storage electrodes 133 may vary.

An interlayer insulating layer 140 comprising a material such as silicon nitride (SiNx) or silicon dioxide (SiOx) is formed on the gate lines 121 and the storage electrode lines 131. A portion of the interlayer insulating layer 140 which is disposed on the gate electrode 124 functions as a gate insulator.

Data lines 171 and drain electrodes 175 are formed on the interlayer insulating layer 140.

The data lines 171 transmit data signals and extend in a longitudinal direction. Each data line 171 includes a source electrode 173 extending toward the gate electrode 124 and an end portion 179 having a wide area for connection with another layer or an external driving circuit.

The data line 171 includes a double-layered structure, wherein a lower layer thereof has a thickness of about 2500-3500 Å and an upper layer thereof has a thickness of about 10-50 Å. In detail, the data line 171 includes a lower data line 171p having a lower source electrode 173p and an upper data line 171q having an upper source electrode 173q.

The lower data line 171p and the upper data line 171q have substantially the same plane shape, and the upper data line 171q covers (for example, completely covers) the lower data line 171p. This structure may be achieved, as will be described later, by forming the data line 171 through a lift-off process or a process using a shadow mask.

The drain electrode 175 includes a portion facing the source electrode 173 and a portion overlapping the storage electrode 133. The drain electrode 175 also has a double-layered structure, and includes a lower drain electrode 175p with a thickness of about 2500-3500 Å and an upper drain electrode 175q with a thickness of about 10-50 Å.

The lower drain electrode 175p and the upper drain electrode 175q have substantially the same plane shape, and the upper drain electrode 175q covers (for example, completely covers) the lower drain electrode 175p. This structure may be achieved, as will be described later, by forming the drain electrode 175 through a lift-off process or a process using a shadow mask.

The lower data line 171p and the lower drain electrode 175p may comprise a low resistance metal such as molybdenum (Mo), copper (Cu), rubidium (Ru), vanadium (V), chromium (Cr), zinc (Zn), indium (In), and/or aluminum (Al), and as these metal wirings have low resistance, they may prevent or reduce a signal delay.

The upper data line 171q and the upper drain electrode 175q may comprise a resistance metal oxide including molybdenum (Mo), copper (Cu), rubidium (Ru), vanadium (V), chromium (Cr), zinc (Zn), indium (In), and/or aluminum (Al). The upper data line 171q and the upper drain electrode 175q may comprise the same metal oxide as the metal for the lower data line 171p and the lower drain electrode 175p.

The reason that the lower data line 171p and the lower drain electrode 175p respectively have substantially the same plane shape as the upper data line 171q and the upper drain electrode 175q is for the lower data line 171p, the upper data line 171q, the lower drain electrode 175p, and the upper drain electrode 175q to be simultaneously formed through the lift-off process or through the deposition process using the same shadow mask. These processes may reduce the cost of the manufacturing process for the thin film transistor array panel.

An organic semiconductor 154 is formed between the upper source electrode 173q and the upper drain electrode 175q. The organic semiconductor 154 overlaps the gate electrode 124. The organic semiconductor 154 contacts the upper source electrode 173q and the upper drain electrode 175q. The organic semiconductor 154 may be thinner than the source electrode 173 or the drain electrode 175, or may be thicker.

The organic semiconductor 154 may include a high molecular weight compound and a low molecular weight compound that is dissolved in an aqueous solution or an organic solvent and formed by an Inkjet printing process. However, the organic semiconductor 154 may be formed by another solution process such as a spin coating, slit coating, or a deposition process.

The organic semiconductor 154 may include polythienylenevinylene, poly3-hexylthiophene, polythiophene, phthalocyanine, metalized phthalocyanine, halogenation derivatives thereof, or a mixture thereof. The organic semiconductor 154 may include perylenetetracarboxylic dianhydride (PTCDA), naphthalenetetracarboxylic dianhydride (NTCDA), imide derivatives thereof, or a mixture thereof. The organic semiconductor 154 may include a derivative including perylene or coronene, and substitution groups thereof.

The upper source electrode 173q and the upper drain electrode 175q cover (for example, completely cover) the lower source electrode 173p and the lower drain electrode 175p such that the upper source electrode 173q and the upper drain electrode 175q directly contact the organic semiconductor 154. Accordingly, the upper source electrode 173q and the upper drain electrode 175q have a function of reducing the Schottky barrier between the organic semiconductor 154, and the lower source electrode 173p and the lower drain electrode 175p as an ohmic contact, thereby providing for a thin film transistor with desirable characteristics. The upper source electrode 173q and the upper drain electrode 175q may form the metal oxide and perform the function of the ohmic contact.

For example, when the organic semiconductor 154 comprises pentacene, the lower data line 171p and the lower drain electrode 175p comprise Cu and the upper data line 171q and the upper drain electrode 175q comprise CuO. Here, the value of the work function of pentacene is about 5.0 eV, and the value of the work function of CuO is about 5.0-5.3 eV and thus the contact resistance between pentacene and CuO is low thereby providing for a thin film transistor with desirable characteristics. Also, the value of the work functions of MoOx and VOx are about 5.2-5.5 eV respectively, and the value of the work function of RuOx is about 4.8-5.1 eV such that the characteristics of the thin film transistor are increased, as the case with CuO. The work function values of the above-described oxide metals are about 4.8-5.5 eV.

Also, when using the metal oxide of the metal with the low cost such as copper (Cu) and molybdenum (Mo), the cost of the manufacturing process may be reduced. Furthermore, the structure in which the lower portion of the organic semiconductor 154 contacts the source electrode 173 and the drain electrode 175 is referred to as a bottom contact structure.

A gate electrode 124, a source electrode 173, and a drain electrode 175 form a thin film transistor (TFT) along with an organic semiconductor 154, and the channel of the thin film transistor is formed in the organic semiconductor 154 between the source electrode 173 and the drain electrode 175.

A passivation layer 180 is formed on the organic semiconductor 154. The passivation layer 180 has a contact hole 185 exposing the drain electrode 175. The passivation layer 180 may comprise an insulating material such as a fluorine-based hydrocarbon compound or a polyvinyl alcohol-based compound, and may protect the organic semiconductor 154 from external heat, plasma, and chemical substances.

A pixel electrode 191 and contact assistants 81 and 82 are formed on the passivation layer 180.

The pixel electrode 191 is connected to the drain electrode 175 through the contact hole 185, and receives the data voltage from the drain electrode 175. The pixel electrode 191 overlaps the storage electrode 133 to form a storage capacitor.

The contact assistants 81 and 82 are respectively connected to the end portions 129 and 179 of the gate lines 121 and the data lines 171 through contact holes 181 and 182. The contact assistants 81 and 82 may enhance the adhesion between the end portions 129 and 179 of the gate lines 121 and data lines 171, and external devices such as a gate driver or a data driver, and may protect them.

The pixel electrode 191 and the contact assistants 81 and 82 may comprise a transparent conductive material or a reflective metal. When the driver IC is directly formed on the substrate 110, at least one of the contact assistants 81 and 82 may be omitted.

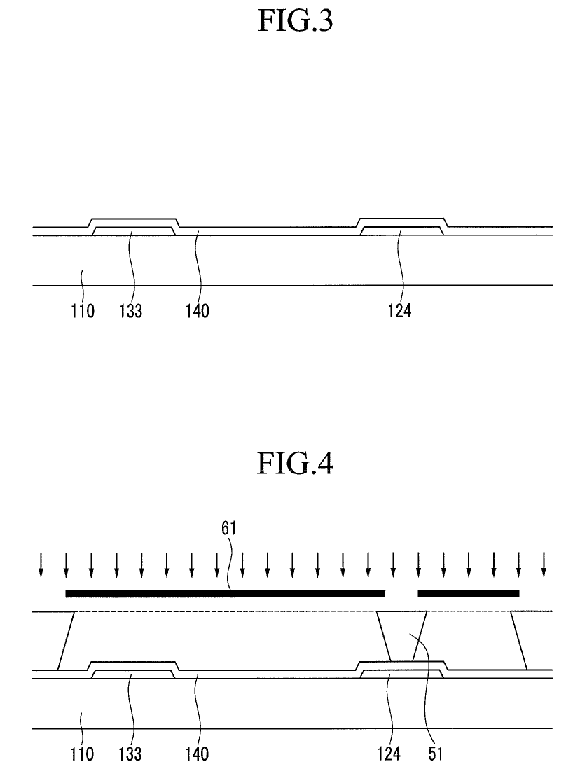

Now, a manufacturing method of the thin film transistor array panel shown in FIG. 1 and FIG. 2 will be described with reference to FIG. 3 to FIG. 16.

FIG. 3 to FIG. 8 are layout views sequentially showing a method for manufacturing an organic thin film transistor array panel shown in FIG. 1 and FIG. 2 according to an exemplary embodiment of the present invention.

Firstly, as shown in FIG. 3, a metal layer is deposited on a substrate 110 and patterned by photolithography to form a gate line 121 including a gate electrode 124 and an end portion 129, and a storage electrode line 131 including a storage electrode 133. Next, an interlayer insulating layer 140 is deposited on the substrate 110, the gate line 121, and the storage electrode line 131.

Next, as shown in FIG. 4, a negative photosensitive material is coated on the interlayer insulating layer 140 to form a first photosensitive film 51, and is exposed and developed by using a first mask 61 that is patterned for a data line 171 including a source electrode 173 and a drain electrode 175. Accordingly, a portion that is not irradiated by light among the first photosensitive film 51 is removed and a portion that is irradiated by light remains with a reverse taper structure.

Next, as shown in FIG. 5, a data metal layer 170p is deposited on the interlayer insulating layer 140 and the first photosensitive film 51, and a data metal oxide layer 170q is deposited thereon. Here, the remaining first photosensitive film 51 has a reverse taper structure such that the data metal oxide layer 170q covers (for example, completely covers) the side surface of the data metal layer 170p.

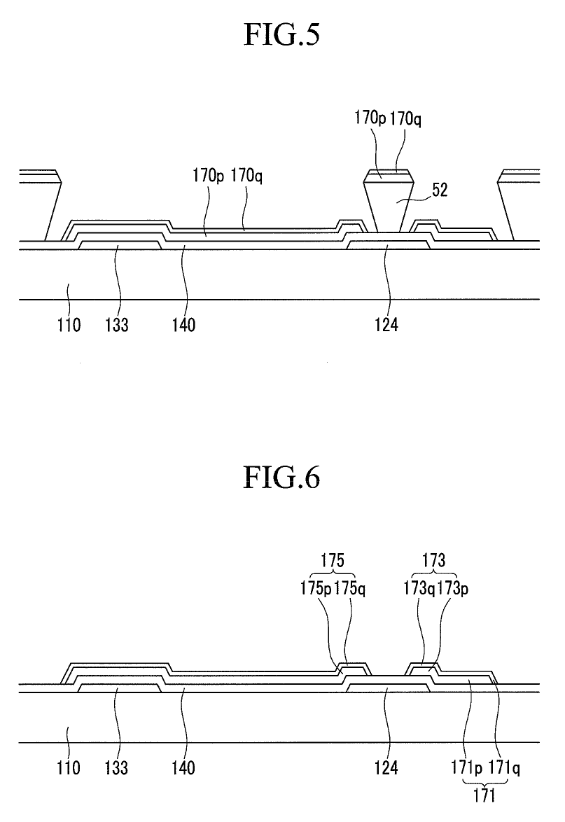

Next, as shown in FIG. 6, the remaining first photosensitive film 51 is removed by using an etchant.

The process as above-described in FIG. 4 to FIG. 6 is referred to as a lift-off process. Generally, when the source or drain electrodes including the metal layer and the metal oxide are formed by the general photolithography, the etch cross-section of the double layers is not uniform due to the differences of the etch degree. Accordingly, the portion actually contacting the semiconductor may be the metal layer rather than the metal oxide layer, and there is a problem in that the contact resistance between the semiconductor and the electrode may be increased.

However, in the case of the lift-off process as above-described in FIG. 4 to FIG. 6, the data metal oxide layer 170q contacts (for example, always contacts) the organic semiconductor 154 such that the contact resistance is reduced, thereby providing for a thin film transistor with desirable characteristics. Also, when the source electrode 173 and the drain electrode 175 are formed by using a metal oxide having the low cost and the high work function, a thin film transistor array panel having the excellent characteristics and low manufacturing process costs may be provided.

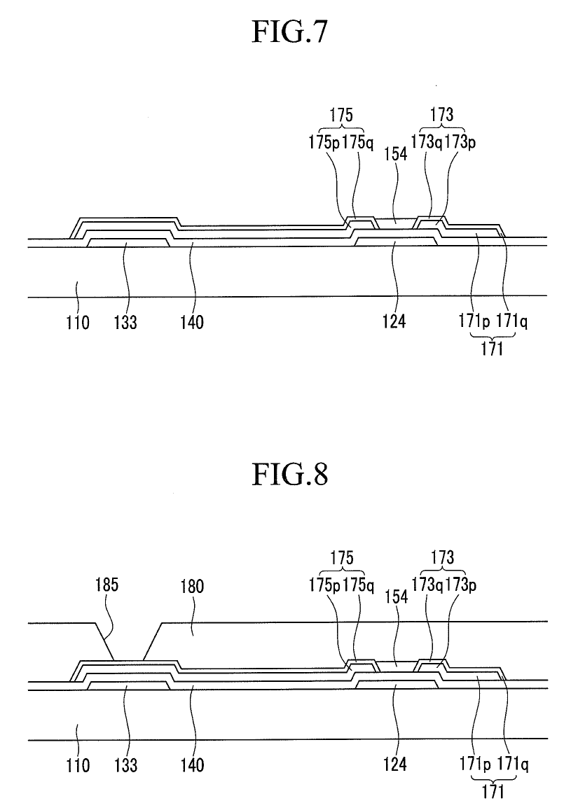

Next, as shown in FIG. 7, the organic semiconductor 154 may be formed by a solution process such as Inkjet printing and spin coating, or a photolithography process.

As shown in FIG. 8, a passivation layer 180 including a photosensitive material is coated, and exposed and developed to form a contact hole 185. Next, a transparent conductive material such as ITO is formed and patterned by photolithography to form a pixel electrode 191.

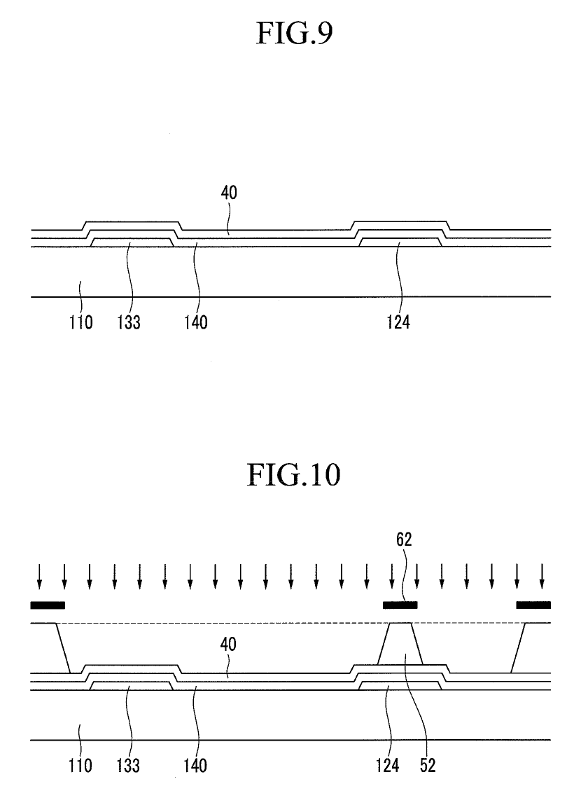

FIG. 9 to FIG. 13 are layout views sequentially showing a method for manufacturing an organic thin film transistor array panel shown in FIG. 1 and FIG. 2 according to an exemplary embodiment of the present invention.

Firstly, as shown in FIG. 9, a metal layer is deposited on a substrate 110 and patterned by photolithography to form a gate electrode 124 and a storage electrode 133. An interlayer insulating layer 140 is then deposited on the gate electrode 124 and the storage electrode 133.

Subsequently, an assistance metal layer 40 is deposited on the interlayer insulating layer 140. The assistance metal layer 40 may comprise a metal of a different kind from that of the data metal layer 170p. In the photolithography method of forming the source electrode 173 and the drain electrode 175, the assistance metal layer 40 is deposited to form the structure in which the data metal oxide layer 170q completely covers the data metal layer 170p.

Next, as shown in FIG. 10, a positive photosensitive material is coated on the assistance metal layer 40 to form a second photosensitive film 52, and is exposed and developed by using a second mask 62 that is patterned to form a data line 171 including a source electrode 173 and a drain electrode 175. Accordingly, the portion of the second photosensitive film 52 that is irradiated by light is all removed and the portion thereof that is not irradiated by light remains. Also, a negative photosensitive material may be used instead of the positive photosensitive material. In this case, a process that will be described later is similarly executed except that the direction of the inclination surface of the second photosensitive film 52 is changed into a reverse taper from a normal taper.

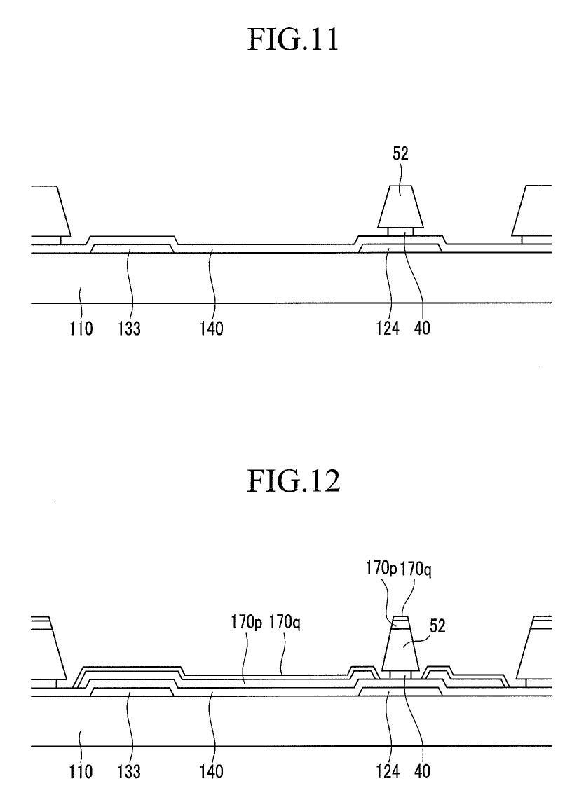

Next, as shown in FIG. 11, if the assistance metal layer 40 is wet-etched, the assistance metal layer 40 is removed except for the portion under the second photosensitive film 52. Here, both ends of the assistance metal layer 40 under the second photosensitive film 52 are over-etched such that the undercut structure is formed under the second photosensitive film 52.

Next, as shown in FIG. 12, a data metal layer 170p including a different metal from that of the assistance metal layer 40 is formed on the interlayer insulating layer 140 and the second photosensitive film 52, and a data metal oxide layer 170q is deposited. Here, the undercut is formed under the remaining second photosensitive film 52 such that the data metal oxide layer 170q covers (for example, completely covers) the data metal layer 170p.

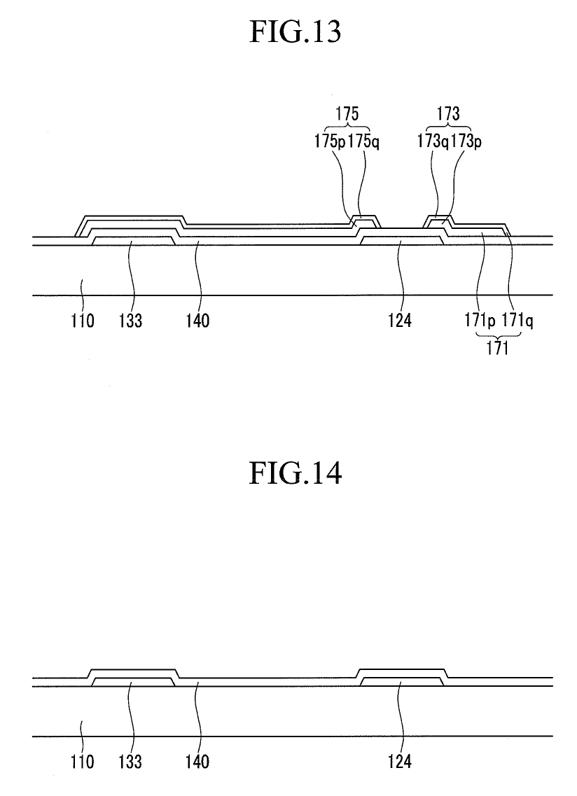

Next, as shown in FIG. 13, the remaining second photosensitive film 52 and the assistance metal layer 40 are selectively removed by using an etchant having selectivity.

FIG. 10 to FIG. 13 illustrate a lift-off process of a different type than described above with respect to FIG. 4 to FIG. 6. Accordingly, the merits described in the process of FIG. 4 to FIG. 6 may apply to the process of FIG. 10 to FIG. 13.

The process for forming the organic semiconductor 154, the passivation layer 180, and the pixel electrode 191 is a similar method to that of FIG. 7 and FIG. 8.

FIG. 14 to FIG. 16 are layout views sequentially showing a method for manufacturing an organic thin film transistor array panel shown in FIG. 1 and FIG. 2 according to an exemplary embodiment of the present invention.

Firstly, as shown in FIG. 14, a metal layer is deposited on a substrate 110 and patterned by photolithography to form a gate electrode 124 and a storage electrode 133. Next, an interlayer insulating layer 140 is deposited on the gate electrode 124 and the storage electrode 133.

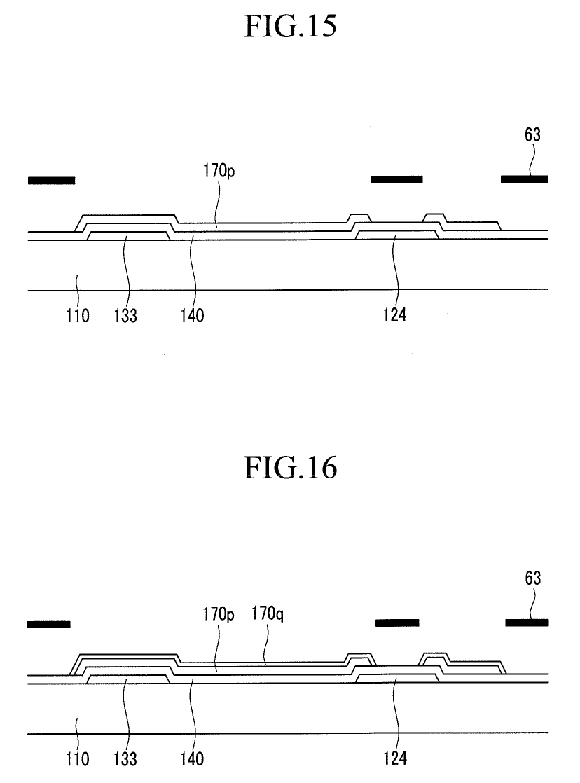

Then, as shown in FIG. 15, a third mask 63 for forming a data line 171 including a source electrode 173 and a drain electrode 175 is aligned.

As shown in FIG. 15 and FIG. 16, after aligning the third mask 63, a data metal layer 170p and a data metal oxide layer 170q are then sequentially deposited through sputtering. In this case, the data metal layer 170p and the data metal oxide layer 170q are selectively deposited through the opening of the third mask 63 thereby accumulating under the opening of the third mask 63. The third mask 63 is referred to as a shadow mask. Here, the data metal oxide layer 170q covers (for example, completely covers) the data metal layer 170p. Accordingly, the process using the shadow mask may be applied with the merits of the process of FIG. 4 to FIG. 6.

The process for forming the organic semiconductor 154, the passivation layer 180, and the pixel electrode 191 is similar to the method of FIG. 7 and FIG. 8.

While exemplary embodiments of the present invention have been described in connection with the figures, it is to be understood that the invention is not limited to the disclosed exemplary embodiments, and the invention is intended to cover various modifications and equivalent arrangements.

What is claimed is:

1. A thin film transistor array panel comprising:
a gate line comprising a gate electrode;
an interlayer insulating layer disposed on the gate line;
a data line disposed on the interlayer insulating layer, the data line comprising a source electrode;
a drain electrode facing the source electrode;
an organic semiconductor disposed between the source electrode and the drain electrode; and
a pixel electrode connected to the drain electrode,
wherein the data line comprises a first data line and a second data line and the drain electrode comprises a first drain electrode and a second drain electrode, and wherein:
the first data line and the first drain electrode comprise a metal;
the second data line and the second drain electrode are disposed on the first data line and the first drain electrode; and
the second data line and the second drain electrode each comprise a metal oxide.

2. The thin film transistor array panel of claim 1, wherein
the organic semiconductor contacts the second data line and the second drain electrode.

3. The thin film transistor array panel of claim 2, wherein
a top surface of the first data line has substantially the same shape as a top surface of the second data line, and a top surface of the first drain electrode has substantially the same shape as a top surface of the second drain electrode.

4. The thin film transistor array panel of claim 3, wherein
the second data line fully covers the first data line, and the second drain electrode fully covers the first drain electrode.

5. The thin film transistor array panel of claim 4, wherein
the edge of the second data line covers the edge of the first data line, and the edge of the second drain electrode covers the edge of the second data line.

6. The thin film transistor array panel of claim 2, wherein
the organic semiconductor contacts the interlayer insulating layer.

7. The thin film transistor array panel of claim 1, wherein
the metal and the metal oxide each comprise a first metal.

8. The thin film transistor array panel of claim 7, wherein
the first metal is molybdenum (Mo), copper (Cu), rubidium (Ru), vanadium (V), chromium (Cr), zinc (Zn), indium (In), or aluminum (Al).

9. The thin film transistor array panel of claim 7, wherein
the value of the work function of the metal oxide is in the range of about 4.8-5.5 eV.

10. The thin film transistor array panel of claim 1, wherein
the organic semiconductor is disposed on the second data line and the second drain electrode.

11. The thin film transistor array panel of claim 1, further comprising
a passivation layer disposed on the organic semiconductor, the second data line, and the second drain electrode.

12. The thin film transistor array panel of claim 1, wherein
the organic semiconductor is thinner than either the source electrode or the drain electrode.

13. A method for manufacturing a thin film transistor array panel, comprising:
forming a gate line comprising a gate electrode;
forming an interlayer insulating layer on the gate line;
forming a photosensitive film pattern on the interlayer insulating layer and thereby forming a data line comprising a source electrode and a drain electrode;
depositing a data metal layer on the photosensitive film pattern and the interlayer insulating layer;
forming a data metal oxide layer on the data metal layer;
removing the photosensitive film pattern; and
forming an organic semiconductor between the source electrode and the drain electrode.

14. The method of claim 13, wherein
the photosensitive film comprises a negative photosensitive material.

15. The method of claim 13, wherein
the organic semiconductor is formed on the metal oxide layer and the organic semiconductor contacts the metal oxide layer.

16. The method of claim 15, wherein
the data metal layer and the data metal oxide each comprise a first metal.

17. The method of claim 16, wherein
the first metal comprises molybdenum (Mo), copper (Cu), rubidium (Ru), vanadium (V), chromium (Cr), zinc (Zn), indium (In), or aluminum (Al).

18. The method of claim 13, further comprising
forming a passivation layer on the organic semiconductor.

19. The method of claim 18, further comprising
forming a pixel electrode on the passivation layer.

20. A method for manufacturing a thin film transistor array panel, comprising:
forming a gate line comprising a gate electrode;
forming an interlayer insulating layer on the gate line;
forming an assistance metal layer on the interlayer insulating layer;
forming a photosensitive film pattern on the assistance metal layer and thereby forming a data line comprising a source electrode and a drain electrode;
etching the assistance metal layer by using the photosensitive film pattern as a mask;
depositing a data metal layer on the photosensitive film pattern and the interlayer insulating layer;
forming a data metal oxide layer on the data metal layer;
removing the photosensitive film pattern and the assistance metal layer; and
forming an organic semiconductor between the source electrode and the drain electrode.

21. The method of claim 20, wherein
the organic semiconductor is formed on the metal oxide layer and the organic semiconductor contacts the metal oxide layer.

22. The method of claim 20, wherein
the data metal layer and the data metal oxide comprise the first metal.

23. The method of claim 22, wherein
the first metal comprises molybdenum (Mo), copper (Cu), rubidium (Ru), vanadium (V), chromium (Cr), zinc (Zn), indium (In), or aluminum (Al).

24. A method for manufacturing a thin film transistor array panel, comprising:
forming a gate line comprising a gate electrode;
forming an interlayer insulating layer on the gate line;
aligning a mask on the interlayer insulating layer and thereby forming a data line comprising a source electrode and a drain electrode, the mask having at least one opening;
depositing a data metal layer and a data metal oxide layer through the at least one opening of the mask; and
forming an organic semiconductor between the source electrode and the drain electrode.

25. The method of claim 24, wherein
the organic semiconductor is formed on the metal oxide layer and the organic semiconductor contacts the metal oxide layer.

26. The method of claim 24, wherein
the data metal layer and the data metal oxide each comprise a first metal.

27. The method of claim 24, wherein
the first metal comprises molybdenum (Mo), copper (Cu), rubidium (Ru), vanadium (V), chromium (Cr), zinc (Zn), indium (In), or aluminum (Al).
